(19) United States
(12) Patent Application Publication
(10) Pub. No.: US 2026/0255928 A1
(43) Pub. Date: Aug. 27, 2026

(54) SUBSTRATE PROCESSING APPARATUS AND SUBSTRATE PROCESSING

(71) Applicant: JUSUNG ENGINEERING CO., LTD., Gwangju-si, Gyeonggi-do (KR)

(72) Inventors: Won Tae CHO, Yongin-si, Gyeonggi-do (KR); Chul Joo HWANG, Yongin-si, Gyeonggi-do (KR)

(21) Appl. No.: 19/144,912

(22) PCT Filed: Dec. 22, 2023
(86) PCT No.: PCT/KR2023/021371

§ 371 Date: Jun. 30, 2025

(30) Foreign Application Priority Data
Dec. 30, 2022 (KR) 10-2022-0191093
Dec. 21, 2023 (KR) 10-2023-0188634

(51) Int. Cl. H10P 72/76; C23C 16/44; C23C 16/458; H01J 37/32; H10P 72/00

(52) U.S. Cl. CPC H10P 72/7624; C23C 16/4408; C23C 16/4586; H01J 37/3244; H10P 72/0436; H10P 72/7612; H01J 2237/3321

(57) ABSTRACT

The present inventive concept relates to a substrate processing apparatus, including: a chamber; a susceptor supporting a substrate having a tetragonal shape where a length of a side is 730 mm or more; a gas supply unit supplying a gas toward the susceptor; a lift pin inserted into the susceptor to be raised or lowered, the lift pin raising or lowering the substrate; and a lamp heater disposed under the susceptor, and a substrate processing method.

### TECHNICAL FIELD

The present inventive concept relates to a substrate processing apparatus which performs a processing process such as a deposition process and an etching process on a substrate.

### BACKGROUND ART

Generally, a thin-film layer, a thin-film circuit pattern, or an optical pattern should be formed on a substrate for manufacturing a solar cell, a semiconductor device, a flat panel display device, etc. To this end, a processing process is performed on a substrate, and examples of the processing process include a deposition process of depositing a thin film including a specific material on the substrate, a photo process of selectively exposing a portion of a thin film by using a photosensitive material, an etching process of removing the selectively exposed portion of the thin film to form a pattern, etc. Such a processing process on a substrate may be performed by a substrate processing apparatus.

A substrate processing apparatus according to the related art includes a chamber and a susceptor which is disposed in the chamber to support a substrate. In a state where the substrate is supported by the susceptor, the substrate processing apparatus according to the related art performs a processing process on the substrate.

Here, recently, it is required to develop a substrate processing apparatus which may perform a processing process on a substrate having a very large size. However, in a case which intactly uses the substrate processing apparatus according to the related art, there is a problem where it is difficult to perform a processing process on a substrate having a very large size.

### DISCLOSURE

### Technical Problem

The present inventive concept is devised to solve the above-described problem and is for providing a substrate processing apparatus and a substrate processing method, which may perform a processing process on a substrate having a very large size.

### Technical Solution

To accomplish the above-described objects, the present inventive concept may include the following elements.

A substrate processing apparatus according to the present inventive concept may include: a chamber; a susceptor supporting a substrate having a tetragonal shape where a length of a side is 730 mm or more; a gas supply unit supplying a gas toward the susceptor; a lift pin inserted into the susceptor to be raised or lowered, the lift pin raising or lowering the substrate; and a lamp heater disposed under the susceptor.

A substrate processing method according to the present inventive concept may form at least one of a high-k dielectric layer, a channel layer, a metal layer, and an insulation layer by using the substrate processing apparatus.

### Advantageous Effect

According to the present inventive concept, the following effects may be realized.

The present inventive concept is implemented so that a susceptor may support a substrate which is formed to have a side having a very long length. Accordingly, the present inventive concept may be implemented to be suitable for performing a processing process on a substrate having a very large size.

The present inventive concept may be implemented to raise or lower a substrate through raising or lowering of a lift pin. Accordingly, the present inventive concept may perform supporting and spacing of a substrate on a susceptor through raising or lowering of the lift pin, and thus, may enhance the stability of supporting and spacing of the substrate on the susceptor.

### DESCRIPTION OF DRAWINGS

FIG. 1 is a schematic configuration diagram of a substrate processing apparatus according to the present inventive concept.

FIG. 2 is a schematic perspective view of a susceptor in a substrate processing apparatus according to the present inventive concept.

FIG. 3 is a schematic side cross-sectional view of a gas supply unit in a substrate processing apparatus according to the present inventive concept.

FIG. 4 is a timing diagram associated with a time at which a gas is supplied and plasma occurs, in a substrate processing apparatus according to the present inventive concept.

FIG. 5 is a schematic side cross-sectional view of a susceptor and a prop in a substrate processing apparatus according to the present inventive concept.

FIG. 6 is a schematic flowchart of a substrate processing method according to the present inventive concept.

### MODE FOR INVENTIVE CONCEPT

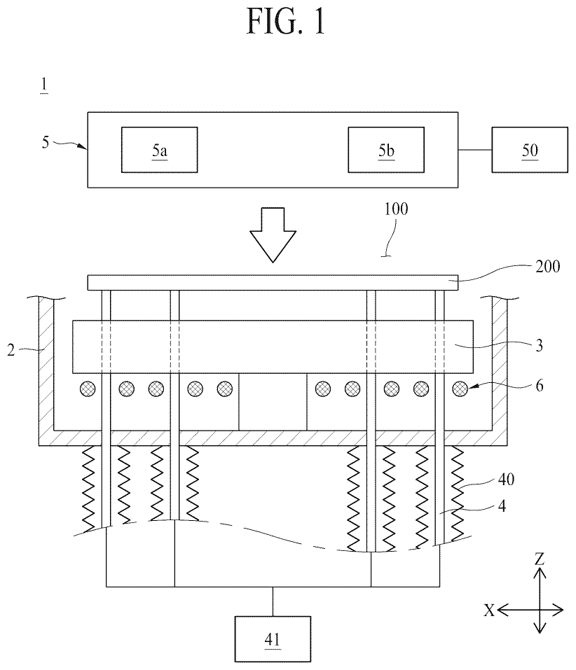

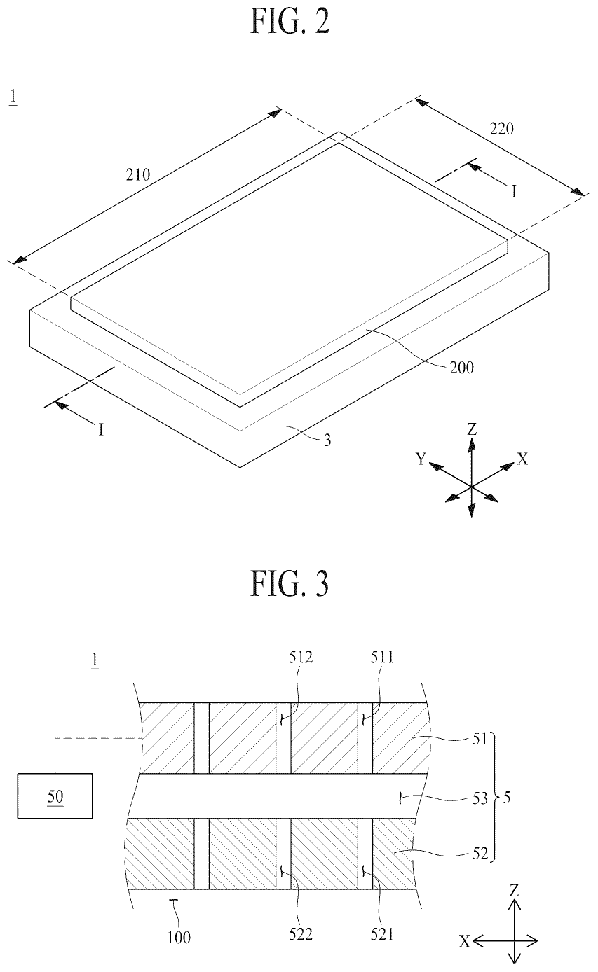

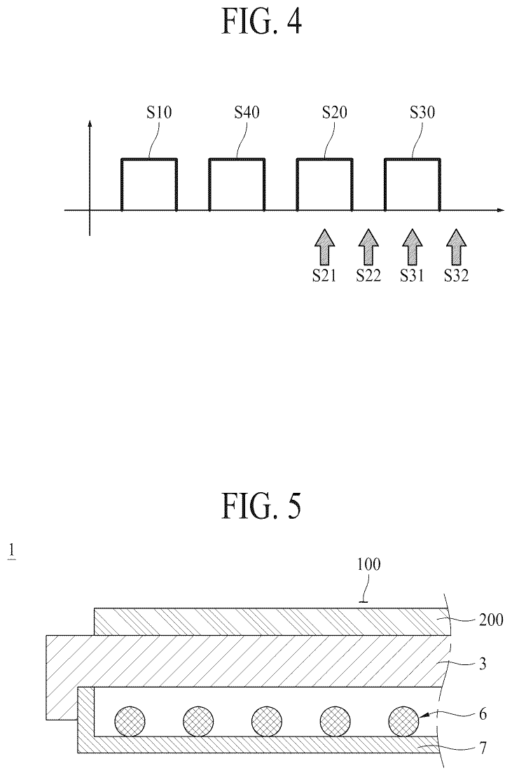

Hereinafter, an embodiment of a substrate processing apparatus according to the present inventive concept will be described in detail with reference to the accompanying drawings. FIGS. 1, 3, and 5 are side cross-sectional views taken along line I-I of FIG. 2. In a timing diagram of FIG. 4, the abscissa axis may be a time, and the ordinate axis may be a flow rate of a gas or a supply pressure of the gas.

Referring to FIGS. 1 and 2, a substrate processing apparatus 1 according to the present inventive concept performs a processing process on a substrate 200. The substrate 200 may be a silicon substrate, a glass substrate, a metal substrate, or the like. The substrate 200 may be a sapphire substrate, a quartz substrate, or the like. The substrate processing apparatus 1 according to the present inventive concept may perform a deposition process of depositing a thin film on the substrate 200, an etching process of removing a portion of the thin film deposited on the substrate 200, etc. Hereinafter, an embodiment where the substrate processing apparatus 1 according to the present inventive concept performs the deposition process will be described mainly, and based thereon, it is obvious to those skilled in the art that an embodiment is devised where the substrate processing apparatus 1 according to the present inventive concept performs another processing process such as the etching process.

The substrate processing apparatus 1 according to the present inventive concept may include a chamber 2, a susceptor 3, a lift pin 4, and a gas supply unit 5.

### Chamber

Referring to FIG. 1, the chamber 2 provides a processing space 100. A processing process on the substrate 200 may be performed in the processing space 100. The processing space 100 may be disposed in the chamber 2. An exhaust port (not shown) which exhausts a gas from the processing space 100 may be coupled to the chamber 2. The susceptor 3 and the gas supply unit 5 may be disposed in the chamber 2.

### Susceptor

Referring to FIGS. 1 and 2, the susceptor 3 may support the substrate 200. The substrate 200 may be formed where a length of a side is 730 mm or more. The substrate 200 may be formed in a tetragonal shape. In this case, the substrate 200 may be formed where a length of a long side 210 is 920 mm or more and a length of a short side 220 is 730 mm or more. Sides of the substrate 200 may be formed to all have the same length. The susceptor 3 may be formed to have a size and a shape capable of supporting the substrate 200. For example, a supporting surface of the susceptor 3 supporting the substrate 200 may be formed to have an area which is greater than the susceptor 3. In this case, the supporting surface may be formed where a length of a side is more than 730 mm. When the substrate 200 is formed where a length of the long side 210 is 920 mm or more and a length of the short side 220 is 730 mm or more, the supporting surface of the susceptor 3 may be formed where a length of a long side is more than 920 mm and a length of a short side is more than 730 mm. For example, the supporting surface of the susceptor 3 may be formed in a tetragonal shape. The susceptor 3 may be formed to have an area which is greater than the substrate 200 and have a shape corresponding to the substrate 200, and thus, the substrate processing apparatus 1 according to the present inventive concept may be implemented to be suitable for performing a processing process on the substrate 200 having a very large size. As illustrated in FIG. 1, the substrate 200 may be supported by the susceptor 3 so that the long side 210 is parallel to the susceptor 3 in a first-axis direction (an X-axis direction) and the short side 220 is parallel to the susceptor 3 in a second-axis direction (a Y-axis direction). The first-axis direction (the X-axis direction) and the second-axis direction (the Y-axis direction) may be axis directions which are disposed to be perpendicular to each other, with respect to one plane.

The susceptor 3 may be formed of a material, which is small in coefficient of thermal expansion and is high in thermal conductance, such as graphite, ceramic, aluminum nitride (AlN), and titanium (Ti). In this case, the substrate processing apparatus 1 according to the present inventive concept may be implemented to be suitable for performing a processing process on the substrate 200 in a very high temperature atmosphere. The susceptor 3 may be formed of one of graphite, ceramic, aluminum nitride, and titanium. The susceptor 3 may be disposed in the chamber 2. The susceptor 3 may be coupled to the chamber 2. The susceptor 3 may be coupled to a supporter, or may be coupled to the chamber 2 through the supporter.

### Lift Pin

Referring to FIGS. 1 and 2, the lift pin 4 may raise or lower the substrate 200. The lift pin 4 may be coupled to the susceptor 3 so as to be raised or lowered. The lift pin 4 may be raised and may protrude to an upper side of the susceptor 3. In this state, the substrate 200 provided into the chamber 2 may be supported by the lift pin 4 through movement, and thus, may be disposed at a position which is upward spaced apart from the susceptor 3. Subsequently, the lift pin 4 may be lowered and may be inserted into the susceptor 3, and thus, the substrate 200 may be supported by the susceptor 3. In a state where the substrate 200 is supported by the susceptor 3, a processing process on the substrate 200 may be performed. While the processing process on the substrate 200 is being performed, the lift pin 4 may be maintained with being inserted into the susceptor 3. When the processing process on the substrate 200 ends, the lift pin 4 may be raised to protrude to the upper side of the susceptor 3, and thus, the processing process-performed substrate 200 may be spaced apart from the susceptor 3. In this state, the substrate 200 may be spaced apart from the lift pin 4 through movement, and then, may be unloaded to the outside of the chamber 2. The movement of the substrate 200 may be performed by a transfer robot (not shown).

As described above, the substrate processing apparatus 1 according to the present inventive concept may be implemented to raise or lower the substrate 200 through raising or lowering of the lift pin 4. Accordingly, the substrate processing apparatus 1 according to the present inventive concept may perform supporting and spacing of the substrate 200 on the susceptor 3 through raising or lowering of the lift pin 4, and thus, may enhance the stability of supporting and spacing of the substrate 200 on the susceptor 3.

The lift pin 4 may raise or lower the substrate 200 so that supporting and spacing of the substrate 200 on the susceptor 3 are performed in a state where the susceptor 3 is fixed. Therefore, the substrate processing apparatus 1 according to the present inventive concept may be implemented not to raise or lower the susceptor 3 which is formed with a very large size, so as to support the substrate 200 having a very large size. Accordingly, the substrate processing apparatus 1 according to the present inventive concept may perform supporting and spacing of the substrate 200 through raising or lowering of the lift pin 4 which is relatively less in weight than the susceptor 3, and thus, the construction cost and the operation cost for implementing raising or lowering of the lift pin 4 may be reduced compared to raising or lowering of the susceptor 3.

The lift pin 4 may be raised or lowered in a vertical direction (a Z-axis direction). The vertical direction (the Z-axis direction) may be an axis direction which is disposed to be perpendicular to each of the first-axis direction (the X-axis direction) and the second-axis direction (the Y-axis direction). The lift pin 4 may be formed in a pole shape or a bar shape having a long length in the vertical direction (the Z-axis direction).

One side of the lift pin 4 may be disposed in the chamber 2, and the other side may be disposed outside the chamber 2. A bellows 40 accommodating the lift pin 4 may be disposed outside the chamber 2. Accordingly, the substrate processing apparatus 1 according to the present inventive concept may be implemented so that an internal pressure of the chamber 2 is stably maintained in a process of raising or lowering the lift pin 4. The bellows 40 may be coupled to a lower surface of the chamber 2, outside the chamber 2.

The lift pin 4 may be raised or lowered by an elevation unit 41. The other side of the lift pin 4 may be coupled to the elevation unit 41. The elevation unit 41 may raise or lower the lift pin 4 through a cylinder scheme using a hydraulic cylinder or a pneumatic cylinder, a ball screw scheme using a ball screw and a ball nut, and a belt scheme using a motor, a pulley, and a belt. The elevation unit 41 may be disposed outside the chamber 2.

The substrate processing apparatus 1 according to the present inventive concept may include a plurality of lift pins 4. The lift pins 4 may be inserted into the susceptor 3 so as to be raised or lowered, at positions apart from one another. Accordingly, the lift pins 4 may support different portions of the substrate 200, and thus, may enhance the stability of supporting and spacing of the substrate 200. The lift pins 4 may be raised or lowered by one elevation unit 41. Although not shown, the substrate processing apparatus 1 according to the present inventive concept may include a plurality of elevation units 41. In this case, the elevation units 41 may individually raise or lower the lift pins 4.

### Gas Supply Unit

Referring to FIGS. 1 to 3, the gas supply unit 5 may supply a gas toward the susceptor 3. The gas supply unit 5 may be disposed to be opposite to the susceptor 3. The gas supply unit 5 may be disposed over the susceptor 3. The processing space 100 may be disposed between the gas supply unit 5 and the susceptor 3. The gas supply unit 5 may be disposed in the chamber 2. The gas supply unit 5 may be disposed to be opposite to the susceptor 3. The gas supply unit 5 may be coupled to a lid (not shown). The lid may be coupled to the chamber 2 to cover an upper portion of the chamber 2. The gas supply unit 5 may be connected to a gas storage unit (not shown). In this case, the gas supply unit 5 may supply a gas, supplied from the gas storage unit, toward the susceptor 3.

The gas supply unit 5 may include a first gas flow path 5a and a second gas flow path 5b.

The first gas flow path 5a is for supplying a first gas. One side of the first gas flow path 5a may be connected to the gas storage unit through a pipe, a hose, a gas block, or the like. The other side of the first gas flow path 5a may connect with the processing space 100. Accordingly, the first gas supplied from the gas storage unit may flow along the first gas flow path 5a, and then, may be supplied to the processing space 100 through the first gas flow path 5a. The first gas flow path 5a may function as a flow path for enabling the first gas to flow and may function as a supply port for supplying the first gas to the processing space 100.

The second gas flow path 5b is for supplying a second gas. The second gas and the first gas may be different gases. For example, when the first gas is a source gas, the second gas may be a reactant gas. One side of the second gas flow path 5b may be connected to the gas storage unit through a pipe, a hose, a gas block, or the like. The other side of the second gas flow path 5b may connect with the processing space 100. Accordingly, the second gas supplied from the gas storage unit may flow along the second gas flow path 5b, and then, may be supplied to the processing space 100 through the second gas flow path 5b. The second gas flow path 5b may function as a flow path for enabling the second gas to flow and may function as a supply port for supplying the second gas to the processing space 100. The second gas flow path 5b and the first gas flow path 5a may supply a gas toward different portions of the processing space 100.

As illustrated in FIG. 3, the gas supply unit 5 may include a first plate 51 and a second plate 52.

The first plate 51 is disposed over the second plate 52. The first plate 51 and the second plate 52 may be disposed apart from each other in the vertical direction (the Z-axis direction). A plurality of first holes 511 may be formed in the first plate 51. The first holes 511 may be formed to pass through the first plate 51. Each of the first holes 511 may function as a path for enabling the first gas to flow. The first holes 511 may be arranged apart from one another in the first-axis direction (the X-axis direction) and the second-axis direction (the Y-axis direction). The first holes 511 may be included in the first gas flow path 4a. A plurality of second holes 512 may be formed in the second plate 52. The second holes 512 may be formed to pass through the first plate 51. Each of the second holes 512 may function as a path for enabling the second gas to flow. The second holes 512 may be arranged apart from one another in the first-axis direction (the X-axis direction) and the second-axis direction (the Y-axis direction). The second holes 512 may be included in the second gas flow path 5b.

The second plate 52 may be disposed between the first plate 51 and the susceptor 3. A plurality of first openings 521 and a plurality of second openings 522 may be formed in the second plate 52.

The first openings 521 may be formed to pass through the second plate 52. The first openings 521 may be respectively disposed at lower sides of the first holes 511. Although not shown, the first openings 521 may be disposed at positions which are vertically and downward apart from the first holes 511. In this case, the first openings 521 are not disposed vertically under each of the first holes 511. The second plate 52 may include more first openings 521 than the number of first holes 511. The first gas may be supplied to the processing space 100 via the first holes 511 and the first openings 521. The first openings 521 may be arranged apart from one another in the first-axis direction (the X-axis direction) and the second-axis direction (the Y-axis direction). The first holes 511 and the first openings 521 may be included in the first gas flow path 5a. The first openings 521 may be connected to a buffer space 53 disposed between the first plate 51 and the second plate 52. The first gas may be supplied to the processing space 100 via the first holes 511, the buffer space 53, and the first openings 521. The first holes 511, the buffer space 53, and the first openings 521 may be included in the first gas flow path 5a.

The second openings 522 may be formed to pass through the second plate 52. The second openings 522 may be respectively disposed at lower sides of the second holes 512. Although not shown, the second openings 522 may be disposed at positions which are vertically and downward apart from the second holes 512. In this case, the second openings 522 are not disposed vertically under each of the second holes 512. The second plate 52 may include more second openings 522 than the number of second holes 512. The second openings 522 may be connected to the buffer space 53. The second gas may be supplied to the processing space 100 via the second holes 512, the buffer space 53, and the second openings 522. The second openings 522 may be arranged apart from one another in the first-axis direction (the X-axis direction) and the second-axis direction (the Y-axis direction). The second holes 512, the buffer space 53, and the second openings 522 may be included in the second gas flow path 5b.

Furthermore, a lower surface of the first plate 51 facing the second plate 52 may be formed to be flat. Although not shown, the gas supply unit 5 may include a plurality of protrusion members which protrude toward the first plate 51 from the lower surface of the first plate 51. The protrusion members may be formed with a length which enables the protrusion members to be respectively inserted into the first openings 521. The protrusion members may be formed with a length which is disposed over each of the first openings 521. In this case, the protrusion members may contact an upper surface of the second plate 52. The protrusion members may be formed with a length which protrudes to a lower side of the second plate 52. In a case where the protrusion members are provided, the first holes 511 may be formed to pass through the first plate 51 and the protrusion members. Accordingly, the first gas flow path 5a and the second gas flow path 5b may be spatially spaced apart from each other.

The gas supply unit 5 may include a power supply unit 50.

The power supply unit 50 may apply power to the first plate 51 or the second plate 52. In a case where the power supply unit 50 applies power to the first plate 51 or the second plate 52, the gas supply unit 5 may generate plasma. In a case where the power supply unit 50 is implemented to apply power to the first plate 51, the second plate 52 may be grounded. In a case where the power supply unit 50 is implemented to apply power to the second plate 52, the first plate 51 may be grounded. The power supply unit 50 may apply a plasma power such as radio frequency (RF) power to the first plate 51 or the second plate 52.

Referring to FIGS. 1 to 4, the gas supply unit 5 may supply a gas toward the susceptor 3 as follows.

First, the gas supply unit 5 may supply a source gas toward the susceptor 3 (S10). In this case, the gas supply unit 5 may supply the source gas through the first gas flow path 5a.

Subsequently, the gas supply unit 5 may supply a reactant gas toward the susceptor 3 (S20). In this case, the gas supply unit 5 may supply the reactant gas through the second gas flow path 5b.

The gas supply unit 5 may sequentially or simultaneously supply the source gas and the reactant gas. In a case where the gas supply unit 5 sequentially supplies the source gas and the reactant gas, the substrate processing apparatus 1 according to the present inventive concept may perform a processing process based on an atomic layer deposition (ALD) process. In this case, the gas supply unit 5 may supply the source gas through the first gas flow path 5a and may then supply the reactant gas through the second gas flow path 5b. In a case where the gas supply unit 5 simultaneously supplies the source gas and the reactant gas, the substrate processing apparatus 1 according to the present inventive concept may perform a processing process based on a chemical vapor deposition (CVD) process. In this case, when the gas supply unit 5 supplies the source gas through the first gas flow path 5a, the gas supply unit 5 may supply the reactant gas through the second gas flow path 5b.

After the gas supply unit 5 supplies the reactant gas (S20), the gas supply unit 5 may supply a purge gas toward the susceptor 3 (S30). In this case, the gas supply unit 5 may supply the purge gas through at least one of the first gas flow path 5a and the second gas flow path 5b. The purge gas may be an inert gas such as argon.

After the gas supply unit 5 supplies the source gas (S10), the gas supply unit 5 may supply the purge gas toward the susceptor 3 (S40). In this case, the gas supply unit 5 may supply the purge gas through at least one of the first gas flow path 5a and the second gas flow path 5b. After the gas supply unit 5 supplies the purge gas toward the susceptor 3 (S40), the gas supply unit 5 may supply the reactant gas toward the susceptor 3 (S20).

Here, the gas supply unit 5 may generate plasma by using the power supply unit 50 in a process of supplying a gas toward the susceptor 3. Accordingly, the substrate processing apparatus 1 according to the present inventive concept may perform crystallization, film densification, and impurities removal on a thin film formed on the substrate 200, and thus, may enhance the quality of the processing process-performed substrate 200. This will be described below in detail.

First, when the gas supply unit 5 supplies the reactant gas (S20), the power supply unit 50 may apply power to the first plate 51 or the second plate 52 to generate plasma (S21). Accordingly, processing based on the reactant gas and processing based on the plasma may be performed in parallel on the substrate 200 supported by the susceptor 3.

Subsequently, after the gas supply unit 5 supplies the reactant gas (S20) and before the gas supply unit 5 supplies the purge gas (S30), the power supply unit 50 may apply power to the first plate 51 or the second plate 52 to generate plasma (S22). Accordingly, after the processing based on the reactant gas is performed, processing based on the plasma may be performed on the substrate 200 supported by the susceptor 3.

Subsequently, when the gas supply unit 5 supplies the purge gas (S30) after the gas supply unit 5 supplies the reactant gas (S20), the power supply unit 50 may apply power to the first plate 51 or the second plate 52 to generate plasma (S31). Accordingly, processing based on the purge gas and processing based on the plasma may be performed in parallel on the substrate 200 supported by the susceptor 3.

Subsequently, after the gas supply unit 5 supplies the purge gas (S30), the power supply unit 50 may apply power to the first plate 51 or the second plate 52 to generate plasma (S32). Accordingly, after the processing based on the purge gas is performed, processing based on the plasma may be performed on the substrate 200 supported by the susceptor 3.

Furthermore, the substrate processing apparatus 1 according to the present inventive concept may perform plasma processing using the power supply unit 50 in at least one of sections S21, S22, S31, and S32 described above.

Here, the substrate processing apparatus 1 according to the present inventive concept may be implemented so that a source gas including gallium (Ga) is supplied through the first gas flow path 5a and a reactant gas including nitrogen (N) is supplied through the second gas flow path 5b by using the gas supply unit 5, and thus, a thin film including gallium nitride (GaN) is formed on the substrate 200. In this case, the thin film including gallium nitride (GaN) may be implemented as a channel layer or a semiconductor layer. The substrate processing apparatus 1 according to the present inventive concept may perform a processing process on the substrate 200, and thus, may form at least one of a high-k dielectric layer, a channel layer, a metal layer, and an insulation layer. The high-k dielectric layer and the channel layer may be formed of a high-k dielectric material such as hafnium (Hf) or zirconium (Zr). The metal layer may be a wiring metal layer for wiring. The insulation layer may be formed of silica (SiO). The substrate processing apparatus 1 according to the present inventive concept may form a thin film for manufacturing a thin film transistor (TFT) and a thin film for manufacturing a light emitting diode (LED, on the substrate 200.

Referring to FIGS. 1 to 5, the substrate processing apparatus 1 according to the present inventive concept may include a lamp heater 6.

The lamp heater 6 may adjust a temperature of the processing space 100. The lamp heater 6 may heat the processing space 100, and thus, may adjust the processing space 100 to a process temperature. In this case, the lamp heater 6 may emit heating light to heat the processing space 100. The lamp heater 6 may adjust the processing space 100 to a process temperature of 400° C. or more. Accordingly, the substrate processing apparatus 1 according to the present inventive concept may be implemented to be suitable for performing a processing process on the substrate 200 having a very large size in a very high temperature atmosphere. In this case, the susceptor 3 may be formed of a material, which is small in coefficient of thermal expansion and is high in thermal conductance, such as graphite, and thus, may be implemented to stably support the substrate 200 in a very high temperature atmosphere.

The lamp heater 6 may be disposed under the susceptor 3. Therefore, the substrate processing apparatus 1 according to the present inventive concept may decrease an adverse effect, where a gas supplied toward the susceptor 3 from the gas supply unit 5 pollutes the lamp heater 6, on the lamp heater 6. Therefore, the substrate processing apparatus 1 according to the present inventive concept may enhance the accuracy of process temperature adjustment using the lamp heater 6, and thus, may more enhance the quality of the process processing-performed substrate 200. Also, the substrate processing apparatus 1 according to the present inventive concept may increase a period requiring maintenance such as replacement and repair on the lamp heater 6, and thus, may decrease the maintenance cost of the lamp heater 6 and may increase an operation rate, thereby increasing the productivity of the process processing-performed substrate 200. With respect to the vertical direction (the Z-axis direction), the lamp heater 6 may be disposed at a position where a distance apart from the susceptor 3 is shorter than a distance apart from a floor of the chamber 2. Accordingly, the substrate processing apparatus 1 according to the present inventive concept may reduce an interval between the lamp heater 6 and the susceptor 3, and thus, may more decrease an adverse effect of a gas, supplied toward the susceptor 3 from the gas supply unit 5, on the lamp heater 6.

The substrate processing apparatus 1 according to the present inventive concept may include a plurality of lamp heaters 6. The lamp heaters 6 may be disposed apart from one another. Therefore, the lamp heaters 6 may heat different portions of the processing space 100, and thus, may uniformly adjust a temperature of the processing space 100. The lamp heaters 6 may be disposed to configure a pattern at a lower side of the susceptor 3. For example, a plurality of lamp heaters 6 may be disposed apart from one another along a first row, a plurality of lamp heaters 6 may be disposed apart from one another along a second row apart from the first row, and the lamp heaters 6 disposed in the first row and the lamp heaters 6 disposed in the second row may be disposed at staggered positions. In this case, the lamp heaters 6 disposed in the first row and the lamp heaters 6 disposed in the second row may partially overlap at staggered positions. As described above, the lamp heaters 6 may be spaced apart from one another along a plurality of rows and may be disposed to configure a pattern.

Referring to FIGS. 1 to 5, the substrate processing apparatus 1 according to the present inventive concept may include a prop 7 (illustrated in FIG. 5).

The prop 7 may be coupled to the susceptor 3. The prop 7 may be coupled to the susceptor 3 at a lower side of the susceptor 3. The prop 7 may configure a lower portion of the susceptor 3. The prop 7 may support the lamp heater 6 so that the lamp heater 6 is disposed at the lower side of the susceptor 3. In this case, with respect to the vertical direction (the Z-axis direction), the lamp heater 6 may be disposed between the susceptor 3 and the prop 7. Therefore, the prop 7 may protect the lamp heater 6 from a gas supplied by the gas supply unit 5. Therefore, the substrate processing apparatus 1 according to the present inventive concept may more decrease an adverse effect of a gas, supplied toward the susceptor 3 from the gas supply unit 5, on the lamp heater 6. The prop 7 and the susceptor 3 may be formed of one of graphite, ceramic, aluminum nitride, and titanium.

Although not shown, the substrate processing apparatus 1 according to the present inventive concept may include an edge frame.

The edge frame may be disposed at a side surface of the susceptor 3. While a processing process on the substrate 3 is being performed, the edge frame may indicate a portion of an upper surface of the susceptor 3. For example, the edge frame may indicate the other portion except a portion of the susceptor 3 covered by the substrate 200. Therefore, the edge frame may prevent particles from being unnecessarily deposited on the upper surface of the susceptor 3. Accordingly, the substrate processing apparatus 1 according to the present inventive concept may increase a cleaning period of the susceptor 3 by using the edge frame, and thus, may decrease the cleaning cost of the susceptor 3 and may increase an operation rate, thereby increasing the productivity of the process processing-performed substrate 200.

Hereinafter, an embodiment of a substrate processing method according to the present inventive concept will be described in detail with reference to the accompanying drawings.

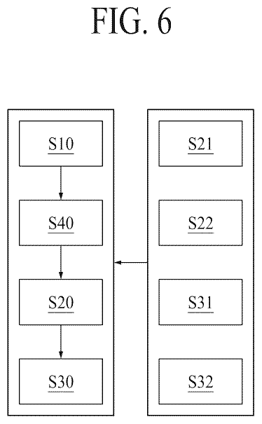

Referring to FIGS. 1 to 6, the substrate processing method according to the present inventive concept performs a processing process on the substrate 200. The substrate processing method according to the present inventive concept may be performed by using the substrate processing apparatus 1 according to the present inventive concept described above. In this case, the substrate processing method according to the present inventive concept may form at least one of a high-k dielectric layer, a channel layer, a metal layer, and an insulation layer by using the substrate processing apparatus 1 according to the present inventive concept. The substrate processing method according to the present inventive concept may include step S10 of supplying a source gas and step S20 of supplying a reactant gas.

Step S10 of supplying the source gas supplies the source gas toward the susceptor 3. Step S10 of supplying the source gas may be performed by supplying the source gas through the first gas flow path 5a by using the gas supply unit 5. This case may be a state where the substrate 200 is supported by the susceptor 3. The substrate 200 may be formed where a length of a side is 730 mm or more. The substrate 200 may be formed in a tetragonal shape. In this case, the substrate 200 may be formed where a length of the long side 210 is 920 mm or more and a length of the short side 220 is 730 mm or more. Sides of the substrate 200 may be formed to all have the same length. The susceptor 3 may be formed to have a size and a shape capable of supporting the substrate 200. The susceptor 3 may be formed to have an area which is greater than the substrate 200 and have a shape corresponding to the substrate 200, and thus, the substrate processing method according to the present inventive concept may be implemented to be suitable for performing a processing process on the substrate 200 having a very large size.

Step S20 of supplying the reactant gas supplies the reactant gas toward the susceptor 3. Step S20 of supplying the reactant gas may be performed by supplying the reactant gas through the second gas flow path 5b by using the gas supply unit 5.

In the substrate processing method according to the present inventive concept, step S10 of supplying the source gas and step S20 of supplying the reactant gas may be sequentially or simultaneously performed. In a case where step S10 of supplying the source gas and step S20 of supplying the reactant gas are sequentially performed, the substrate processing method according to the present inventive concept may perform a processing process based on an atomic layer deposition (ALD) process. In a case where step S10 of supplying the source gas and step S20 of supplying the reactant gas are simultaneously performed, the substrate processing method according to the present inventive concept may perform a processing process based on a chemical vapor deposition (CVD) process.

Here, step S10 of supplying the source gas may be performed by supplying the source gas after adjusting the processing space 100 to a process temperature. Adjusting the processing space 100 to a process temperature may be performed by the lamp heater 6. The lamp heater 6 may continuously or intermittently operate so that the processing space 100 is maintained at a process temperature even when step S10 of supplying the source gas is being performed. The lamp heater 6 may continuously or intermittently operate so that the processing space 100 is maintained at a process temperature while a processing process including step S10 of supplying the source gas is being performed on the substrate 200.

Here, step S10 of supplying the source gas may be performed after the substrate 200 is supported by the susceptor 3. Supporting the substrate 200 with the susceptor 3 may be performed by the lift pin 4. In a state where the lift pin 4 is raised to protrude to an upper side of the susceptor 3, the substrate 200 loaded into the chamber 2 may be supported by the lift pin 4 through movement, and thus, may be disposed at a position which is upward apart from the susceptor 3. Subsequently, the lift pin 4 may be lowered and inserted into the susceptor 3, and thus, the substrate 200 may be supported by the susceptor 3. In a state where the substrate 200 is supported by the susceptor 3, step S10 of supplying the source gas may be performed. While a processing process including step S10 of supplying the source gas is being performed on the substrate 200, the lift pin 4 may be maintained with being inserted into the susceptor 3. As described above, the substrate processing method according to the present inventive concept may be implemented to raise or lower the substrate 200 through raising or lowering of the lift pin 4. Accordingly, the substrate processing method according to the present inventive concept may perform supporting and spacing of the substrate 200 on the susceptor 3 through raising or lowering of the lift pin 4, and thus, may enhance the stability of supporting and spacing of the substrate 200 on the susceptor 3.

The substrate processing method according to the present inventive concept may include step S30 of supplying a purge gas, after step S20 of supplying the reactant gas. Step S30 of supplying the purge gas supplies the purge gas toward the susceptor 3. Step S30 of supplying the purge gas may be performed by supplying the purge gas through at least one of the first gas flow path 5a and the second gas flow path 5b.

The substrate processing method according to the present inventive concept may include step S40 of supplying a purge gas, after step S10 of supplying the source gas. Step S40 of supplying the purge gas supplies the purge gas toward the susceptor 3. Step S40 of supplying the purge gas may be performed by supplying the purge gas through at least one of the first gas flow path 5a and the second gas flow path 5b. Step S20 of supplying the reactant gas may be performed after step S40 of supplying the purge gas is performed.

The substrate processing method according to the present inventive concept may generate plasma by using the power supply unit 50 in a process of supplying a gas toward the susceptor 3. Accordingly, the substrate processing method according to the present inventive concept may perform crystallization, film densification, and impurities removal on a thin film formed on the substrate 200, and thus, may enhance the quality of the processing process-performed substrate 200.

To this end, the substrate processing method according to the present inventive concept may include step S21 of generating plasma when step S20 of supplying the reactant gas is performed. Such a step S21 may be performed by generating plasma as the power supply unit 50 applies power to the first plate 51 or the second plate 52, when the gas supply unit 5 supplies a reactant gas through the second gas flow path 5b. Accordingly, processing based on a reactant gas and processing based on plasma may be performed in parallel on the substrate 200 supported by the susceptor 3.

The substrate processing method according to the present inventive concept may include step S22 of generating plasma after step S20 of supplying the reactant gas is performed and before step S30 of supplying the purge gas. Such a step S22 may be performed by generating plasma as the power supply unit 50 applies power to the first plate 51 or the second plate 52, after the gas supply unit 5 supplies the reactant gas through the second gas flow path 5b and before the gas supply unit 5 supplies the purge gas through at least one of the first gas flow path 5a and the second gas flow path 5b. Accordingly, after processing based on a reactant gas is performed, processing based on plasma may be performed on the substrate 200 supported by the susceptor 3. After step S22 of generating the plasma is performed, step S30 of supplying the purge gas may be performed.

The substrate processing method according to the present inventive concept may include step S31 of generating plasma when step S30 of supplying the purge gas is performed, after step S20 of supplying the reactant gas is performed. Such a step S31 may be performed by generating plasma as the power supply unit 50 applies power to the first plate 51 or the second plate 52, when the gas supply unit 5 supplies the purge gas through at least one of the first gas flow path 5a and the second gas flow path 5b after the gas supply unit 5 supplies the reactant gas through the second gas flow path 5b. Accordingly, processing based on a reactant gas and processing based on plasma may be performed in parallel on the substrate 200 supported by the susceptor 3.

The substrate processing method according to the present inventive concept may include step S32 of generating plasma after step S30 of supplying the purge gas is performed. Such a step S32 may be performed by generating plasma as the power supply unit 50 applies power to the first plate 51 or the second plate 52, after the gas supply unit 5 supplies the purge gas through at least one of the first gas flow path 5a and the second gas flow path 5b. Accordingly, after processing based on a purge gas is performed, processing based on plasma may be performed on the substrate 200 supported by the susceptor 3. After step S32 of generating the plasma is performed, step S10 of supplying the source gas may be performed.

The present inventive concept described above are not limited to the above-described embodiments and the accompanying drawings and those skilled in the art will clearly appreciate that various modifications, deformations, and substitutions are possible without departing from the scope and spirit of the inventive concept.

1. A substrate processing apparatus comprising:
a chamber;
a susceptor supporting a substrate having a tetragonal shape where a length of a side is 730 mm or more;
a gas supply unit supplying a gas toward the susceptor;
a lift pin inserted into the susceptor to be raised or lowered, the lift pin raising or lowering the substrate; and
a lamp heater disposed under the susceptor.

2. The substrate processing apparatus of claim 1, wherein the lamp heater adjusts a processing space between the gas supply unit and the susceptor to a process temperature of 400° C. or more.

3. The substrate processing apparatus of claim 1, wherein the susceptor is formed of at least one of graphite, ceramic, aluminum nitride (AlN), and titanium (Ti).

4. The substrate processing apparatus of claim 1, wherein the gas supply unit comprises:
a first plate disposed over the susceptor;
a second plate disposed between the first plate and the susceptor;
a plurality of first holes and a plurality of second holes formed to pass through the first plate;
a plurality of first openings and a plurality of second openings formed to pass through the second plate; and
a power supply unit applying power to the first plate or the second plate.

5. The substrate processing apparatus of claim 4, wherein a lower surface of the first plate facing the second plate is formed to be flat.

6. The substrate processing apparatus of claim 4, wherein the gas supply unit comprises a first gas flow path for supplying a gas toward the susceptor and a second gas flow path for supplying a gas toward the susceptor,
the first gas flow path comprises the first holes and the first openings, and
the second gas flow path comprises the second holes and the second openings.

7. The substrate processing apparatus of claim 6, wherein the gas supply unit supplies a source gas through the first gas flow path and supplies a reactant gas through the second gas flow path.

8. The substrate processing apparatus of claim 7, wherein, when the gas supply unit supplies a reactant gas, the power supply unit applies power to the first plate or the second plate to generate plasma.

9. The substrate processing apparatus of claim 7, wherein the gas supply unit supplies a purge gas through at least one of the first gas flow path and the second gas flow path after supplying a reactant gas, and
after the gas supply unit supplies a reactant gas and before the gas supply unit supplies a purge gas, the power supply unit applies power to the first plate or the second plate to generate plasma.

10. The substrate processing apparatus of claim 7, wherein the gas supply unit supplies a purge gas through at least one of the first gas flow path and the second gas flow path after supplying a reactant gas, and
when the gas supply unit supplies a purge gas, the power supply unit applies power to the first plate or the second plate to generate plasma.

11. The substrate processing apparatus of claim 7, wherein the gas supply unit supplies a purge gas through at least one of the first gas flow path and the second gas flow path after supplying a reactant gas, and
after the gas supply unit supplies a purge gas, the power supply unit applies power to the first plate or the second plate to generate plasma.

12. The substrate processing apparatus of claim 7, wherein the gas supply unit supplies a reactant gas through the second gas flow path after supplying a source gas through the first gas flow path.

13. The substrate processing apparatus of claim 7, wherein the gas supply unit supplies a reactant gas through the second gas flow path when supplying a source gas through the first gas flow path.

14. The substrate processing apparatus of claim 1, wherein the lift pin raises or lowers the substrate so that supporting and spacing of the substrate are performed on the susceptor in a state where the susceptor is fixed.

15. The substrate processing apparatus of claim 1, comprising a prop coupled to the susceptor to support the lamp heater so that the lamp heater is disposed under the susceptor.

16. A substrate processing method comprising forming at least one of a high-k dielectric layer, a channel layer, a metal layer, and an insulation layer by using the substrate processing apparatus of claim 1.

17. A substrate processing method comprising forming at least one of a high-k dielectric layer, a channel layer, a metal layer, and an insulation layer by using the substrate processing apparatus of claim 2.
